(19) United States
(12) Patent Application Publication
(10) Pub. No.: US 2011/0143137 A1
(43) Pub. Date: Jun. 16, 2011

(54) Composite Nanorods

(75) Inventors: Paul A. Alivisatos, Berkeley, CA (US); Richard Robinson, Ithaca, NY (US); Bryce Sadtler, Los Angeles, CA (US)

(73) Assignee: THE REGENTS OF THE UNIVERSITY OF CALIFORNIA, Oakland, CA (US)

(21) Appl. No.: 12/668,193

(22) PCT Filed: Jul. 8, 2008
(86) PCT No.: PCT/US08/69384

§ 371 Date: Dec. 9, 2010

Related U.S. Application Data
(60) Provisional application No. 60/948,971, filed on Jul. 10, 2007.
(60) Provisional application No. 60/987,547, filed on Nov. 13, 2007.

(51) Int. Cl. H01L 23/00; D02G 1/00; C09K 11/08; B82Y 40/00; B82Y 99/00; B82Y 30/00

(52) U.S. Cl. 428/373; 428/402; 252/301.4 R; 977/842; 977/734; 977/774; 977/762

(57) ABSTRACT

A method is disclosed. The method includes forming a mixture including nanorods with a first material having first ions, coordinating molecules, and second ions in a solvent, and forming composite nanorods in the solvent. Each composite nanorod has a linear body with a first region having the first material and a second region having a second material, where the second material has the second ions.

### CROSS-REFERENCES TO RELATED APPLICATIONS

This patent application is a non-provisional of and claims priority to U.S. Provisional Application Nos. 60/948,971, filed on Jul. 10, 2007, and 60/987,547, filed on Nov. 13, 2007. All of the above applications are herein incorporated by reference in their entirety for all purposes.

### STATEMENT AS TO RIGHTS TO INVENTIONS MADE UNDER FEDERALLY SPONSORED RESEARCH OR DEVELOPMENT

The invention described and claimed herein was made in part utilizing funds supplied by the U.S. Department of Energy under Contract No. DE-AC02-05CH11231. The Government has certain rights in this invention.

### BACKGROUND OF THE INVENTION

### Field of the Invention

Embodiments of the invention relate generally to the synthesis of colloidal nanorod superlattices through a single-step, partial cation exchange reaction.

The ability to pattern on the nanoscale has led to a wide range of advanced artificial materials with controllable quantum energy levels. Structures such as quantum dot arrays and nanowire heterostructures can be fabricated by vacuum and vapor deposition techniques such as molecular beam epitaxy (MBE) and vapor-liquid-solid (VLS), resulting in quantum confined units that are attached to a substrate or are embedded in a solid medium. A target of colloidal nanocrystal research is to create these and other structures while leveraging the advantages of solution-phase fabrication, such as low-cost synthesis and compatibility in disparate environments (e.g., for use in biological labeling, and solution-processed light-emitting diodes and solar cells).

Quantum dots are nanoparticles that have been studied extensively. One key difference between quantum dots epitaxially grown on a substrate and free-standing colloidal quantum dots is the presence of strain. In epitaxially grown systems, the interface between the substrate crystal and the quantum dot creates a region of strain surrounding the dot. Ingeniously, this local strain has been used to create an energy of interaction between closely spaced dots; this use of “strain engineering” has led, in turn, to quantum dot arrays which are spatially patterned in two (and even three) dimensions. In embodiments of the invention, the application of strain engineering in a colloidal quantum dot system can be demonstrated by introducing a method that spontaneously creates a regularly spaced arrangement of quantum dots within a colloidal quantum rod.

One-dimensional semiconducting superlattices are a promising new generation of materials that offer advanced electronic, photonic, and thermoelectric properties. Unique to nanorod and nanowire superlattices are their dimensional confinement effects and their ability to tolerate large amounts of lattice mismatch without forming dislocations and degrading device performance. When the materials have opposite Seebeck coefficients, the superlattices can be used as nanometer-sized thermoelectric devices. These junctions are also ideal for studying ionic transport in one-dimensional systems.

The synthesis of nanorod superlattices is too complex to implement by current colloidal methods. The maximum number of alternating layers produced thus far is three, and even this was excessively taxing. Vacuum and vapor methods have been able to create such alternating layers, but these methods are costly, and the finished product remains tethered to a substrate.

Previous work on colloidal and vacuum and vapor heterostructures has relied on time-dependent introduction of precursors, which limits the practical number of alternating layers as each layer is a step.

Thus, what is needed is a way to fabricate a superlattice through colloidal synthesis using a method that does not rely on the time-dependent switching of precursors—a single-step reaction that spontaneously converts a nanorod into a nanorod superlattice.

Embodiments of the invention solve these and other problems, individually and collectively.

### BRIEF SUMMARY OF THE INVENTION

One embodiment of the invention is directed to a method comprising: forming a mixture comprising nanorods comprising a first material comprising first ions, coordinating molecules, and second ions in a solvent; and forming composite nanorods in the solvent, wherein each composite nanorod comprises a linear body comprising a first region comprising the first material and a second region comprising a second material, wherein the second material comprises the second ions.

One embodiment of the invention is directed to a method comprising: forming a mixture comprising nanorods comprising a first material comprising first cations and first anions, coordinating molecules, and second cations and second anions in a solvent; and forming composite nanorods in the solvent, wherein each composite nanorod comprises a linear body comprising a first region comprising the first material and a second region comprising a second material, wherein the second material comprises the second cations and first anions.

Another embodiment of the invention is directed to a one-dimensional nanostructure, comprising: a repeat nanostructure unit comprising: a first layer comprising a first material; and a second layer comprising a second material adjacent the first layer; wherein a series of repeat units are arranged adjacent one another linearly to form a nanostructure superlattice. The number of repeat units of the first material and/or the second material may exceed three.

Another embodiment of the invention is directed to a composite nanorod comprising: a linear body including at least four alternating regions including a first region and a second region, wherein the first region comprises a first material comprising a first ionic compound and the second region comprises a second material comprising a second ionic compound. The number of regions of the first material and/or the second material may exceed three.

These and other embodiments of the invention are described in further detail below.

### BRIEF DESCRIPTION OF THE DRAWINGS

The foregoing aspects and others will be readily appreciated by the skilled artisan from the following description of illustrative embodiments when read in conjunction with the accompanying drawings.

FIGS. 1A-1C show transmission electron micrscopy (TEM) images of superlattices formed through partial cation exchange. FIG. 1A shows 4.8×64 nm CdS nanorods.

FIGS. 1B and 1C show transformed CdS—Ag₂S superlattices. The inset to FIG. 1C is a histogram of Ag₂S segment spacing (center-to-center). Average spacing is 13.8±3.8 nm. The sample set for the histogram was greater than 250 nanorods.

FIGS. 2A and 2B show data that characterizes CdS—Ag₂S heterostructures. FIG. 2A shows energy dispersive spectroscopy (EDS) spectra of the striped rods at the light (top) and dark (bottom) contrast regions or areas, corresponding to Cd—S and Ag—S rich regions, respectively. FIG. 2B shows x-ray diffraction (XRD) spectra of CdS rods, superlattice striped rods, and fully exchanged Ag₂S rods. Spectra from the striped rods show new peaks corresponding to Ag₂S, and a modified (002) peak, indicating interruption of the CdS lattice along the rod axis.

FIGS. 3A-3F show the effects of increasing AgNO₃ concentration. TEM images are shown in FIGS. 3A and 3B. FIG. 3A shows images of nanorod superlattices that are produced at low concentration (Ag⁺/Cd²⁺˜0.2). FIG. 3B shows nanorod superlattices that are produced at an intermediate concentration (Ag⁺/Cd²⁺˜0.9). The scale bar is 20 nm in FIGS. 3A and 3B.

FIGS. 3C and 3D show histograms of the number of Ag₂S regions per rod. FIG. 3C shows the number of Ag₂S regions per rod at low concentration. FIG. 3D shows the number of Ag₂S regions per rod at an intermediate concentration. More than 250 nanorods were examined for each histogram.

FIGS. 3E and 3F show pair distribution histograms for Ag₂S regions on individual CdS—Ag₂S nanorods. FIG. 3E shows data when a low concentration is used to form the CdS—Ag₂S nanorods. FIG. 3F shows data when an intermediate concentration is used to form CdS—Ag₂S nanorods. Intra-rod distances between each Ag₂S region, measured for 200 nanorods in each of the sample sets is shown in FIGS. 3A and 3B. Spacings were normalized by the number of Ag₂S regions and the length of the rod. The low concentration data in FIG. 3E shows no correlation beyond the nearest neighbor spacing. The intermediate concentration data in FIG. 3F shows a periodicity, which extends over several nearest neighbors.

FIGS. 4A-4C show the results of theoretical modeling and experimental optical characterization. FIG. 4A shows a cubic-cutout representation of cells used for ab initio energy calculations. Distorted monoclinic Ag₂S (100) plane connects with the wurtzite CdS (001) plane. FIG. 4B shows elastic energy of rod as a function of segment separation (center-to-center). FIG. 4C shows Z-axis strain for the case of two mismatched segments at a center-to-center separation distance of 14.1 nm (top) and 12.1 nm (bottom). Elastic interaction between segments is greatly reduced for separations >12.1 nm. Arrows show placement of mismatched segments. The CdS rods used for VFF calculations (FIGS. 4B and 4C) were 4.8 nm in diameter with two 4.8×4.0 nm lattice-mismatched segments. Effective elastic constants for the mismatched segments were from ab initio calculations for monoclinic Ag₂S.

FIG. 4D shows visible and FIG. 4E shows NIR photoluminescence (PL) spectra at λ=400 and 550 nm excitation, respectively. Coupling between the CdS and Ag₂S is evident by the complete quenching of the visible PL (D) in the heterostructures. The shift in NIR PL (E) is due to quantum confinement of the Ag₂S.

FIGS. 5A and 5B show diameter dependence of Ag₂S segment spacing. FIG. 5A shows data for 4.8 nm diameter CdS rods. FIG. 5B shows data for 5.3 nm diameter CdS rods. Superlattices were made from two different CdS substrates, one with 4.8 nm diameter nanorods and the other with 5.3 nm diameter nanorods. Spacing increases with rod diameter from 13.8 nm for the 4.8 nm diameter rods to 16.0 nm for the 5.3 nm diameter rods. The center-to-center distance was used to determine spacing. More than 250 rods were measured for each histogram.

FIG. 6 shows a comparison of XRD spectra from (A) nanorod superlattice experiments and (B) numerical simulation. The experimental data is same as in FIG. 2. The simulation is a sum of patterns expected for 5.3×11 nm CdS rods and 5.0 nm Ag₂S cubes. (This is equivalent to an Ag₂S center-to-center spacing of 16 nm.) The simulation spectrum qualitatively matches the experimental spectrum; the Ag₂S peaks at ˜32° and 34° and the broadened shoulder at ˜39° are evident in both the simulated and experimental spectra. Ag₂S peaks appear slightly broader and thus less distinct in the experimental pattern. This can be attributed to the (expected) significant strains in the Ag₂S segments that the simulations do not take into account. Another difference between theoretical and experimental profiles is the lower intensity of the CdS (002) and (103) peaks in the experimental patterns. The weaker than ideal (103) peak is readily explained by the presence of stacking faults in the wurtzite CdS phase. The low (002) intensity is more difficult to explain. It is believed that it is due to non-random alignment of rods on the sample substrate. For these experiments, TEM images show the original CdS rods were 5.3×50 nm, and the striped rods made from these had 5.3×11 nm CdS grains.

FIG. 7 shows a histogram of Ag₂S segment widths (measured along the rod-axis) for the nanorod superlattices shown in FIG. 1. The average width=4.8 nm, standard dev.=22%. More than 250 rods were measured.

FIG. 8 shows schematic illustrations of nanorod superlattices according to embodiments of the invention. As shown, a pure CdS nanorod can be converted to a CdS—Ag₂S composite nanorod through an ion exchange process.

### DETAILED DESCRIPTION

Prior to describing the specific embodiments of the invention, it may be useful to characterize some specific terms including “superlattice” and “nanorod.”

The term “superlattice” is used herein to mean a material with periodically alternating layers or regions of several substances. Such structures possess periodicity both on the scale of each layer's crystal lattice and on the scale of the alternating layers. A superlattice can also be described as a series of thin alternating layers of different materials, with layer thicknesses approaching the inter-atomic spacing period (but may be as large as several hundred layers).

In embodiments of the invention, there can be at least four alternating regions (or layers) per nanorod. In other embodiments, there can be at least six, ten, etc. alternating regions of different materials in a single nanorod and these different materials may be formed in a liquid medium.

The term “nanorod” is used herein to mean any linear nanostructure. An exemplary nanorod according to an embodiment of the invention may exist only as a nanorod may exist as an arm or other part of a larger two or three dimensional particle such as a tetrapod particle or other type of particle.

The composite nanoparticles according to embodiments can be used for any suitable purpose. For example, they can be used to label biological materials, as electronic components in photovoltaic devices, in electronic devices. etc.

As noted above, one embodiment of the invention is directed to a method comprising forming a mixture comprising precursor nanorods comprising a first material comprising first cations and first anions, coordinating molecules, and second cations in a solvent, and then forming composite nanorods in the solvent. Each composite nanorod comprises a linear body comprising a first region comprising the first material and a second region comprising a second material, wherein the second material comprises the second cations and first anions. The first and second regions may alternate in the linear body, and there may be at least two distinct first regions and at least two distinct second regions in the linear body.

In one specific embodiment of the invention, a CdS nanorod is converted into an Ag₂S—CdS nanorod superlattice. The entire CdS nanorod is converted into the superlattice spontaneously by a single step, and thus is not limited by layer-by-layer growth. The CdS nanorod is converted via a partial cation-exchange reaction that results in a free standing Ag₂S—CdS semiconductor superlattice. The linear arrangement of the alternating materials (Ag₂S, CdS) is well organized. The superlattices can be processed in solution and display tunable shifts in photoluminescence from quantum confinement, as expected for the relative alignment of electronic energy levels in the two materials.

Cation exchange provides a facile method for systematically varying the proportion of two chemical compositions within a single nanocrystal. It has been shown that cation exchange can be used to fully (and reversibly) convert CdSe, CdS, and CdTe nanocrystals to the corresponding silver chalcogenide nanocrystal by a complete replacement reaction of the Cd²⁺ cations for Ag⁺ cations. The resultant material is the silver-anion analog of the starting material (i.e., Ag₂Se, Ag₂S, and Ag₂Te). The size and shape of the nanocrystal can be preserved when the nanocrystal has minimum dimensions greater than about 4 nm. The high mobility of cations in the CdS(Se,Te) lattice suggests that partial cation exchange may lead to interesting patterns of segregated domains of silver chalcogenide within a cadmium chalcogenide nanorod. Thus, it seemed there might be a possibility of converting a previously formed nanorod of a single chemical composition into a striped pattern by a single step partial chemical transformation. As disclosed herein, it has been found that a linear arrangement of regularly spaced Ag₂S dots (or regions) contained within a CdS rod forms spontaneously at ˜36% cation exchange. The near-infrared (NIR) bandgap of the Ag₂S dots is embedded within the larger gap of the CdS, creating a type I heterostructure with interesting optical properties.

The above-described nanorods may be formed using any suitable process. In some embodiments, before the mixture is formed, the precursor nanorods may first be formed in solution. For example, the prercursor nanorods can be formed using the methods described in U.S. Pat. Nos. 6,225,198 and 6,306,736. The nanorods may be purely linear structures, or may be arms in two or three-dimensional nanostructures such as nanotetrapods. Such precursor nanorods may consist only of one material (e.g., only CdS) such as one compound semiconductor material. The material in the precursor nanorods may correspond to a first material. The first material may contain first cations (e.g., Cd²⁺), which are exchanged during the composite nanorod formation process, and first anions (e.g., S²⁻) which may remain.

After the precursor nanorods are formed, they may remain in the solution in which they were formed. Alternatively, the precursor nanorods may be in a dry state, and may then be mixed with a solvent to form a solution. In either case, a first solution comprising the precursor nanorods is formed.

Once the first solution is formed, coordinating molecules and second ions may be added to the solution. The second ions (e.g., Ag⁺) may be in the form of an ionic compound (e.g., AgNO₃), along with corresponding second anions (e.g., NO₃⁻) prior to being added to the solution. The ionic compound may be mixed with a second solvent having coordinating molecules (e.g., methanol) to form a second solution, which may be added to the first solution comprising the precursor nanorods comprising the first material (e.g., CdS). When the ionic compound is added to the first solution, the ions forming the ionic compound may dissociate in solution.

A difference concerning this work and prior work on composite nanorods is that there is a spontaneous reorganization of the two materials Ag₂S and CdS to form the alternating pattern that is observed. Prior work on composite nanorods requires iterative process where the growth of each layer in the composite material is a separate step.

Control of temperature may improve the morhphology of the Ag₂S/CdS superlattices during the process of fabricating the composite nanorods according to embodiments of the invention. The control of temperature can be divided into two stages. The first stage includes 1) mixing the above-described first and second solutions at low temperature. The second stage includes reaction of the ionic compound (e.g., AgNO₃) and nanorods (e.g., CdS nanorods), which occurs spontaneously as the temperature is raised to form the composite nanorods (e.g., Ag₂S/CdS nanorods). During the second reaction stage, the second ions in solution may replace some of the first ions in the precursor nanorods through an ion exchange process to form composite nanorods. In the formation of AgS/CdS composite nanorods, second ions such as Ag⁺ ions can replace Cd²⁺ ions in the precursor CdS nanorods. While this procedure consists of two temperature stages, it does not require an iterative step for each layer added to the superlattice as in previous methods.

Illustratively, the first solution may comprise cadmium sulfide (CdS) nanorods in toluene, and the second solution may comprise silver nitrate (AgNO₃) in methanol. Because the reaction between the precursor nanorods and the ionic compound occurs on a millisecond timescale at ambient temperature, lowering the temperature slows down the reaction such that the two solutions can fully mix before the reaction occurs. Thorough mixing is desirable to ensure that the reaction occurs to the same extent among the nanorods in solution, such that the fraction of Ag₂S is similar in each CdS nanorod

The first mixing stage and the second reaction stage can occur at any suitable temperature. A suitable range for the first stage (mixing of the first and second solutions) can be between approximately −100° C. to −60° C. A suitable temperature range for the second stage (reaction of Ag⁺ with CdS) can be approximately −40° C. to 0° C. These temperature ranges are just examples of suitable ranges, and embodiments of the invention are not limited thereto. Having a temperature gap between the two stages ensures mixing of the two solutions occurs before the reaction occurs. In the intermediate range (e.g., −60° C. to −40° C.) mixing and reaction may occur simultaneously.

Embodiments of the invention may have any suitable second ion/first ion molar ratio. For example, the mixture used to form the composite nanorods can have a second ion/first ion molar ratio between about 0 and 5 in some embodiments, and may have a ratio of about 0.70 and 2.5, or less than about 2 in other embodiments. For example, an exemplary ratio of Ag⁺ to Cd²⁺ when forming AgS/CdS composite nanorods can be between 0.7 to 0.9 such that the volume fraction of Ag₂S within the CdS nanorods is 35% to 45%. If the Ag⁺/Cd²⁺ ratio is lower than this range (<0.7), the Ag₂S segments may be small such that they do not span the entire diameter of the nanorod leading to poor ordering of the Ag₂S regions. If the Ag⁺/Cd²⁺ ratio is greater than 0.9 but less than 2 then the Ag₂S segments may begin to merge also leading to poor ordering of the Ag₂S segments. If the Ag⁺/Cd²⁺ ratio is greater than 2, the CdS nanorod may be completely converted to Ag₂S. The previously described ratios and ranges may apply to other first ion and second ion pairs and not just Ag⁺/Cd²⁺. However the ideal ratio for forming the superlattice structure will be dependent on the valency of the first and second ion.

To help facilitate the ion exchange process, coordinating molecules (e.g., methanol) with functional groups such as alcohols, or alkylthiols, alkylamines, alkylphosphines, etc. may be added to the solution. As noted above, the coordinating molecules may be in a second solution comprising the second ions (e.g., Ag⁺). The second solution could optionally include polar solvents such as water, acetonitrile, acetone, dimethylsulfoxide (DMSO), and N,N-dimethylformamide (DMF), and other polar solvents.

The first solution including the precursor nanorods may include any suitable solvent. The solvent may comprise an organic solvent. For example, the solvent may include saturated or unsaturated cyclic (or linear) hydrocarbons alone, or in combination with other molecules. In some cases, the solvent comprises at least one of hexanes, benzene, toluene, cyclohexane, octane or decane. Other examples of suitable solvents include halogenated solvents such as chloroform, tetrachloroethylene, or dichloromethane.

Rapid stirring is desirable in some embodiments. The solution is desirably well-mixed before the reaction occurs. In addition, the first mixing stage and/or the second reaction stage may be performed at ambient pressure in air. The exclusion of oxygen and water may also improve the reaction by performing the reaction at ambient pressure but under an inert atmosphere such as argon or nitrogen.

An exemplary composite nanorod according to an embodiment of the invention may have alternating regions, which alternate down the linear body of a nanorod. The alternating regions may have different materials and may be in any suitable form. For example, the alternating regions may be in the form of alternating layers of different ionic compounds such as CdS and AgS. The ionic compounds may include other types of materials including CdSe, ZnS, ZnSe, PbS, ZnO, CdTe, GaAs, InP, etc.

Although CdS and AgS are described in detail herein as examples of the first material and the second material, the first and second materials may be other materials in other embodiments of the invention. Also, there may be more than two distinct materials in more than two distinct regions in a single linear body in a nanorod in other embodiments of the invention. For example, the first, second, third, etc. materials may comprise semiconductors such as compound semiconductors. Suitable compound semiconductors include Group II-VI semiconducting compounds such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe. Other suitable compound semiconductors include Group III-V semiconductors such as GaAs, GaP, GaAs—P, GaSb, InAs, InP, InSb, AlAs, AlP, and AlSb.

The first ions and the second ions may include any suitable type of ions with any suitable charge states. The first and second ions are typically metal ions. For example, in the examples below, the first ion may be Cd²⁺, while the second ion may be Ag⁺. The first ion and the second ion may have different charges or the same charge.

The second ion may be derived from a precursor compound. In some embodiments, the precursors used to may include Group II, III, IV, V, and/or VI elements. For example, in embodiments of the invention, a region with material to be formed may include a Group II-VI compound semiconductor, which can be the reaction product of at least one precursor containing a Group II metal containing precursor and at least one precursor containing a Group VI element, or a precursor containing both a Group II and a Group VI element. Thus, the second ion may be an ion of a Group II or Group VI element. In other embodiments of the invention, the region of material to be formed may include a Group III-V compound semiconductor, which can be the reaction product of at least one precursor containing a Group III element and at least one precursor containing a Group V element, or a precursor containing both a Group III and a Group V element. The second ion in this example may be an ion of a Group III or V element.

The preferred embodiments that are described below are illustrated in the context of converting a CdS nanorod into an Ag₂S—CdS nanorod superlattice. The skilled artisan will readily appreciate, however, that the materials and methods disclosed herein will have application for a number of other nanorod or nanostructure materials.

There is no limitation on the lengths of the composite nanorods or the number of segments the nanorod superlattices contain. The number of segments per nanorod superlattice will in general increase by increasing the length of the nanorod or decreasing the spacing between like segments.

In previous work, the maximum length (typically 200 nm) obtainable in colloidal nanorods was limited by the solubility of the nanorods. The solubility of the nanorods may also be considered to enable the ion exchange reaction to occur. Methods may be produced in the future for increasing both the maximum length and solubility of colloidal nanorods. Thus, the work included is not limited to a particular length of nanorod precursor

In one embodiment of the invention, FIG. 8 shows a precursor CdS nanorod changing to a CdS—Ag₂S nanorod via the exchange of Cd²⁺ and Ag⁺. As shown in this example, there are three CdS regions and four Ag₂S regions. Each of the three CdS regions may be longer than each of the second Ag₂S regions. In other embodiments, the different regions with different materials may have the same or different lengths, and there can be any suitable number of different regions.

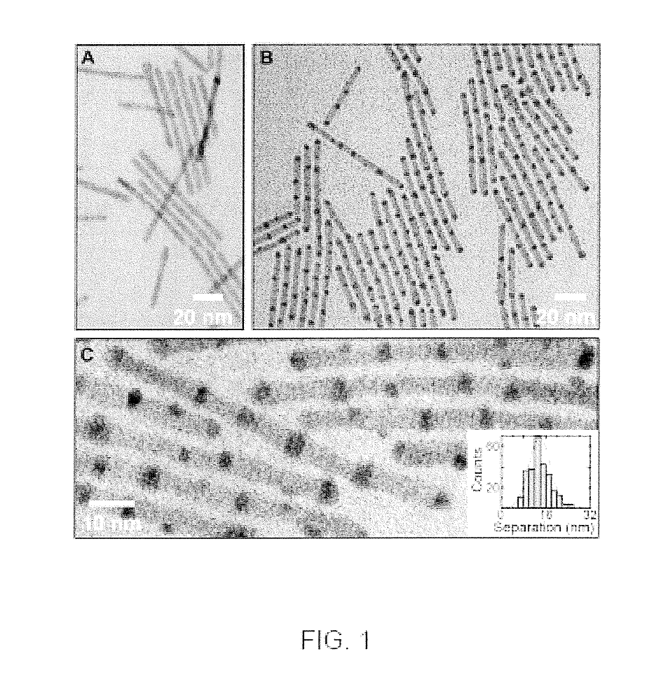

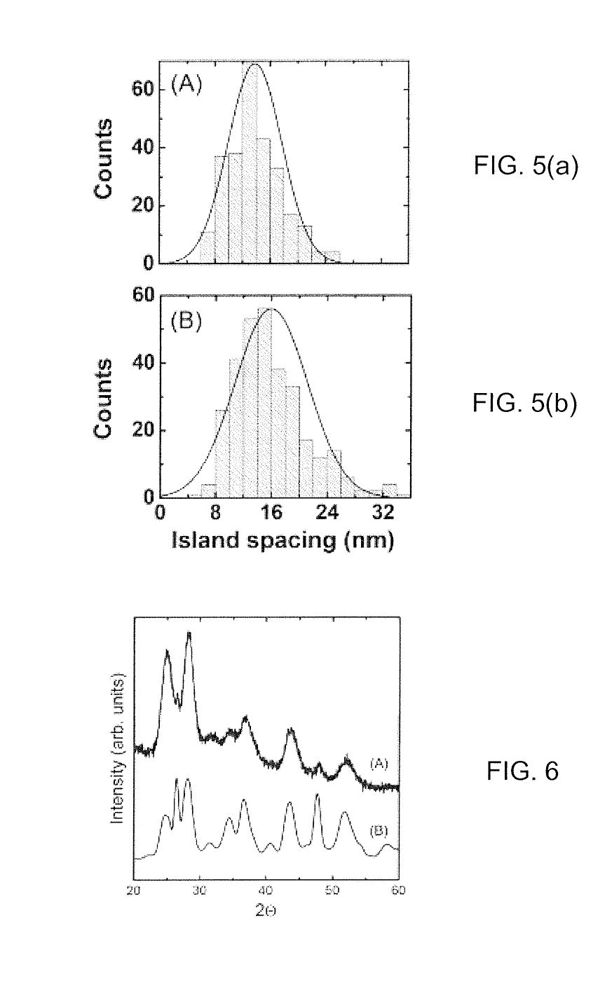

FIGS. 1A-1C show the conversion of CdS nanorods measuring about for 4.8×64 nm to CdS—Ag₂S nanorods as shown in transmission electron microscopy (TEM) images. The initial CdS nanorods (FIG. 1A) are exceptionally smooth and the rod diameter is tightly controlled (std. dev. 10%), while their lengths vary between about 30 and 100 nm. The CdS colloidal nanorods are added to a solution of toluene, AgNO₃, and methanol at −66° C. in air. The concentration of AgNO₃ is a controlled fraction of the concentration of Cd²⁺ ions present in the starting material. In the presence of excess Ag⁺, the rods seem to be converted completely to Ag₂S. However, when the Ag⁺ ions are limited to yield 36% exchange, the resulting nanorods display a periodic pattern of light and dark-contrast regions as shown in FIGS. 1B and 1C. The average spacing between the dark regions is 13.8 nm with a standard deviation of 28% (FIG. 1 histogram inset). The spacing between periodic segments can be controlled by the diameter of the initial CdS rod (FIGS. 5A and 5B).

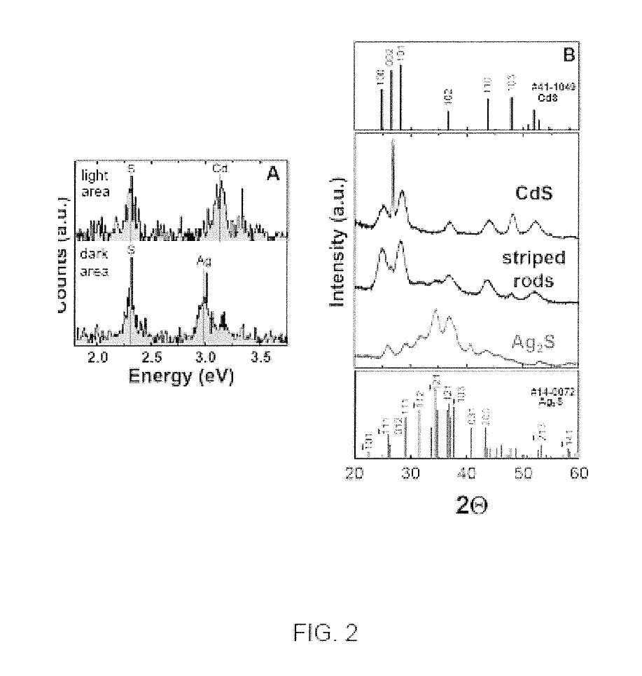

Examination of the light and dark-contrast regions shows that they are CdS and Ag₂S, respectively. As shown in FIG. 2A, energy-dispersive x-ray spectroscopy (EDS) indicates that the striped rods alternate between Cd—S rich regions (light areas) and Ag—S rich regions (dark areas). Powder x-ray diffraction (XRD) data in FIG. 2B confirms the presence of wurtzite CdS and monoclinic Acanthite Ag₂S. Peaks appearing in the original CdS rods can be indexed to wurtzite CdS (JCPDS #41-1049) and those in the fully exchanged rods can be indexed to Acanthite (JCPDS #14-0072). Peaks visible in the striped rods can be attributed purely to a combination of these two phases. No Ag peaks are present. Furthermore, simulation of the XRD pattern (FIG. 6) for a mixture of Ag₂S and CdS crystalline domains with matching agrees qualitatively with the experimental patterns in terms of relative intensities of Ag₂S peaks to CdS peaks, supporting the extent of the conversion observed in TEM images (see FIG. 6).

In experimental XRD patterns, the CdS (002) peak is broader and weaker for the striped rods than for the initial CdS sample. This indicates a decreased CdS crystallite size along <001>, the growth axis of the rods, following the partial ion exchange. Debye-Scherrer analysis of peak widths for several striped rod samples indicates that the CdS grain size along the axis has decreased from more than 30 nm to about 12-16 nm for the striped rods. The decrease in grain size along this direction is attributed to the interruption of the {001} planes by the Ag₂S material, as the shorter length is consistent with the average spacing in this striped rod sample.

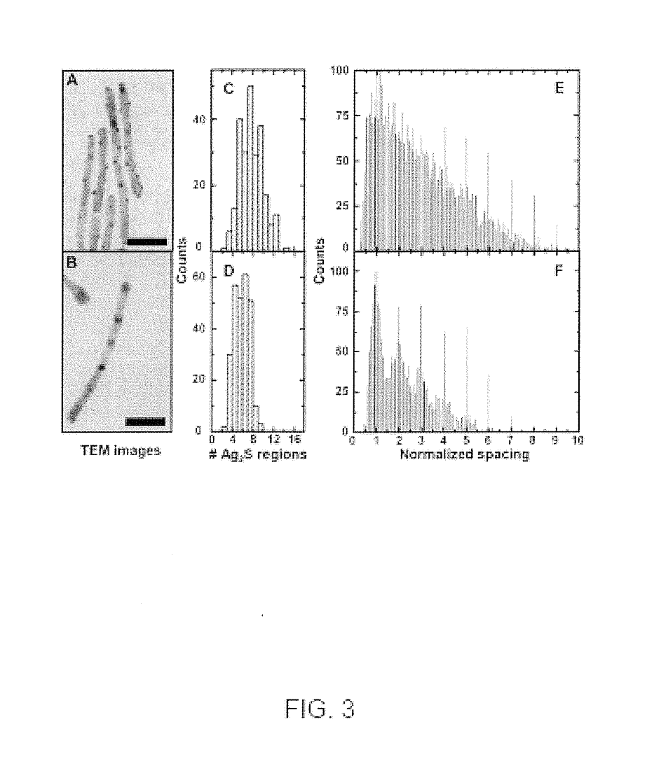

In FIG. 3, TEM images show that the Ag₂S regions, which have a broad range of separations at low concentrations (FIG. 3A), become increasingly ordered at slightly higher concentrations (FIG. 3B). The change in the number and periodicity (spacing) of the Ag₂S regions suggest that a systematic organization develops as the volume fraction of Ag₂S increases (FIGS. 3C-3F). Intra-rod Ag₂S spacings were correlated through a pair distribution function where the distances between each Ag₂S region and all other Ag₂S regions on a rod were measured. Organization of the Ag₂S regions into superlattices is seen in the periodicity of the histogram extending over several nearest neighbor distances, as shown in FIG. 3F. Whereas, the Ag₂S regions in the superlattices are spaced evenly along the rod, no periodicity is seen for the lower Ag⁺ concentration as shown in FIG. 3E.

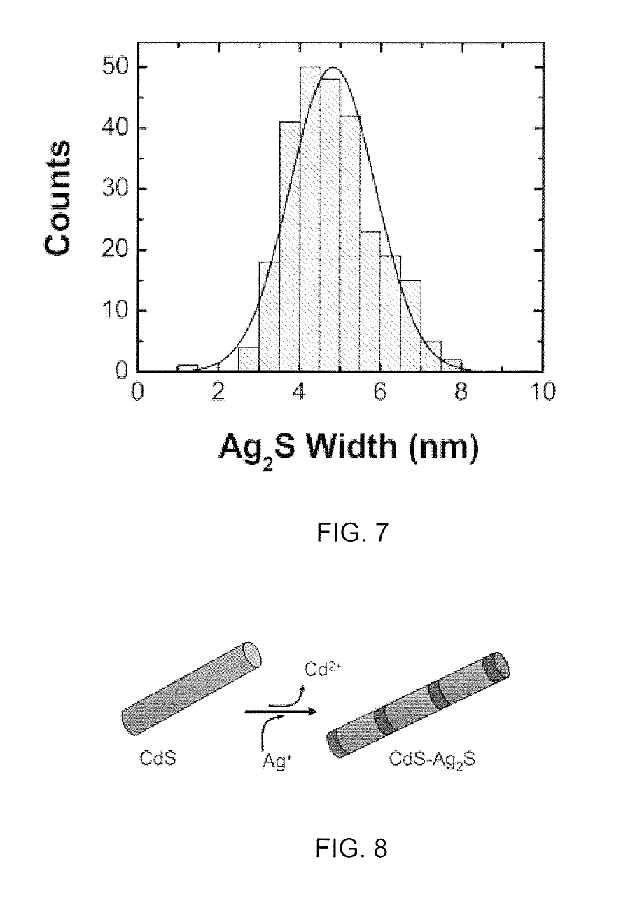

The mechanism by which the initial arrangement of randomly distributed small islands of Ag₂S evolves into a periodic, 1D pattern is of particular interest. Without wishing to be bound to any particular theory, it may be that because there exists a positive CdS—Ag₂S interface formation energy (˜1.68 eV per Cd—Ag—S elementary interface unit, from ab initio calculations), it is energetically favorable to merge small Ag₂S islands into larger Ag₂S segments. Fast diffusion of cations leads to a situation where Ostwald ripening between the initially formed islands of Ag₂S can occur, so that larger islands grow at the expense of nearby smaller ones. Diffusion of the cations is allowed, as both Ag⁺ and Cd²⁺ are considered fast diffusers. Also, silver chalcogenides exhibit superionic conductivity in their high temperature phases. A juncture occurs when the regions of Ag₂S grow to the point where they span the diameter of the rod. At this point, further Ostwald ripening is kinetically prohibited, because an atom-by-atom exchange of Ag⁺ among segments will not reduce the total interfacial area. This leads to Ag₂S segments of nearly equal size (see FIG. 7). The rod is in a metastable state, i.e., the complete joining of two Ag₂S regions is always a lower energy configuration, but one that cannot readily be accessed by simple atomic exchange events.

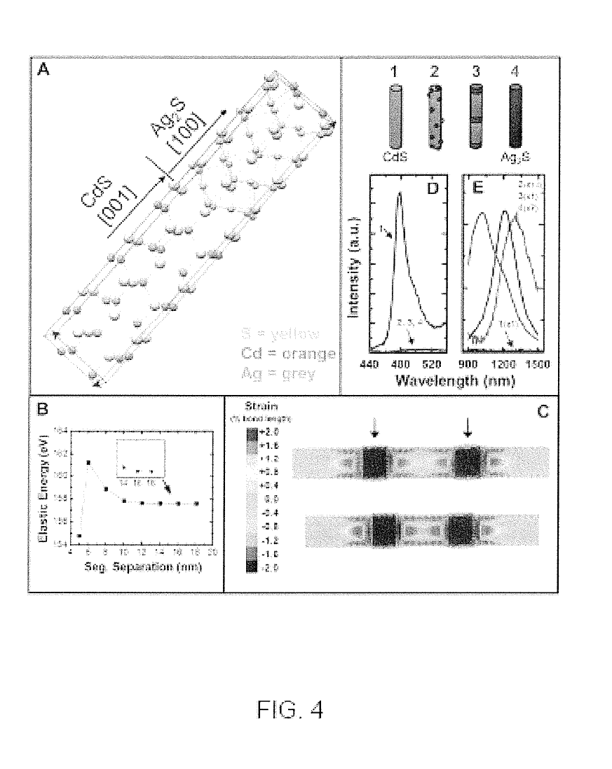

Without wishing to be bound to any particular theory, it may be that the regular spacing of the stripe pattern is promoted by the elastic repulsion between two Ag₂S segments due to the strain in the intervening CdS region. A model for the coherent atomic connection between the two materials is depicted in FIG. 4A. To match the basal lattice constant for CdS (4.3 Å), the Ag₂S body centered cubic lattice in the plane of the interface has to expand 4% in one direction and contract 15% along the perpendicular direction. There is a repulsive elastic force between segments of like material due to the resulting strain fields. Results from Valence Force Field (VFF) modeling found that the elastic energy stored in the rod increases dramatically as two Ag₂S segments approach each other (FIG. 4B). Bond strain in the z-direction (axial) is responsible for the repulsive elastic interaction (FIG. 4C). CdS atoms are pushed away from the closest Ag₂S segment, forming convex shaped atomic layers. For two Ag₂S segments approaching each other, the z-displacements in the CdS are in opposite directions, leading to an interaction term between the fields that give higher strain energy at smaller separations. The model is consistent with the experimental finding that increasing the rod diameter increases the spacing between segments (FIGS. 5A and 5B). Similar effects of spontaneous ordering of quantum dots in two dimensions produced by MBE growth have been explained with corresponding explanations. The one-dimensional geometry, however, explored herein imposes a stronger constraint on ripening processes, leading to an especially robust path to stable, regularly spaced quantum dots within a rod.

The importance of strain in attaining the superlattice pattern can be illustrated by examining similar studies of metal ions reacting with semiconductor nanocrystals. Mokari et. al and Saunders et. al (T. Mokari, E. Rothenberg, I. Popov, R. Costi, U. Banin, Science 304, 1787 (2004), A. E. Saunders, I. Popov, U. Banin, Journal of Physical Chemistry B 110, 25421 (2006), D. Battaglia, B. Blackman, X. G. Peng, Journal of the American Chemical Society 127, 10889 (2005)) have created interesting new metal-semiconductor nanocrystal heterostructures by reducing Au³⁺ ions onto InAs quantum dots and CdS/Se nanorods. As Au³⁺ has a much greater electron affinity than Ag⁺, reduction of the ion takes place rather than an exchange reaction. The positive interfacial energy between the two materials drives phase segregation, similar to the current Ag₂S—CdS system, leading to Ostwald ripening. However, epitaxial strain does not play a significant role in the gold growth, and these heterostructures continue to ripen into single metal domains, either at the tip of the (CdS/Se) rod, or inside the quantum dot (InAs). In contrast, the epitaxial relationship between the two phases in the Ag₂S—CdS superlattice structures result in strain fields from the lattice mismatch, which cause like segments to repel each other preventing further ripening.

The resulting striped rods display properties expected of a type I array of Ag₂S quantum dots separated by confining regions of CdS, in agreement with our ab initio calculations of the band structure. The visible CdS photoluminescence (PL) is quenched indicating coupling between materials at the heterojunction and near-infrared PL from the Ag₂S segments is observed (FIGS. 4D, 4E). The bandgap of the Ag₂S segments depends upon their size, matching the bulk value for fully converted nanorods and shifting to higher energy in smaller dots due to quantum confinement (FIG. 4E). In the present configuration, the Ag₂S quantum dots are only very weakly coupled to each other, because the CdS segments are large. Such structures are of interest for colloidal quantum dot solar cells, where the sparse density of electronic states within a dot may lead to multiple exciton generation. The formation of nanorod superlattices through partial cation exchange can also be applied to other pairs of semiconductors, yielding a broader class of quantum confined structures. Cation exchange reactions have already been reported in HgS, Ag₂S, SnS₂, CdS, ZnS, Cu₂S, Bi₂S₃ and Sb₂S₃. Two component combinations of these can produce materials with functional properties ranging from type I (e.g., ZnS—Ag₂S) and type II (e.g., Cu₂S—CdS) band alignments, to thermoelectric power junctions (e.g., CdS—Bi₂S₃).

The colloidal nanorod superlattices, as disclosed herein are low cost to fabricate and have potential applications in biological labeling and nanoscale optoelectronic devices. Such segmented rods containing many electronically independent dots may be of interest as bright luminescent probes, similar to the use of quantum rods in biolabeling, but with gaps in the near-infrared, facilitating the transmission of the light emission through tissue. The expansion of strain engineering into colloidal systems provides a powerful new tool for fabricating complicated nanoscale architectures. The superlattices presented here display type I electronic bands, and combinations of related materials can create type II alignments and thermoelectric junctions. This discovery offers valuable insight into diffusion and segregation dynamics in low-dimensional systems, and offers a simple, low-cost, yet powerful synthetic method to create a new class of materials.

### EXAMPLES

Chemicals. Cadmium oxide (CdO, 99.99%), silver nitrate (AgNO₃, 99+%), sulfur (99.99%), toluene (99%), and nonanoic acid (96%) were purchased from Aldrich. Isopropanol was purchased from Fisher Scientific and methanol was purchased from Fisher Scientific or EMD Chemicals. Tetradecylphosphonic acid (TDPA) and octadecylphosphonic acid (ODPA) were purchased from Polycarbon Industries (PCI Synthesis, 9 Opportunity Way, Newburyport, Mass. 01950, 978-463-4853). Trioctylphosphine oxide (TOPO, 99%) was purchased from Acros Organics. Tetrachloroethylene was obtained from Kodak. Trioctylphosphine (TOP, 97%) was purchased from Strem Chemicals. Trioctylphosphine sulfide (TOPS) was prepared by mixing TOP and sulfur together in a 1:1 molar ratio in a glovebox followed by stirring at room temperature for >36 hours.

Synthesis of CdS nanorods. Two CdS rod samples were used for the cation exchange reactions in the data reported here. The CdS nanorod dimensions were 4.8±0.5×64±17.6 nm (sample A) and 5.3±0.4×50±10.5 nm (sample B). The reactions were performed using standard Schlenk line techniques. For both reactions 210 mg of CdO and 2.75 g of TOPO were placed in a 25 ml, 3-neck flask. For sample A, 1.06 g of ODPA was added to the flask and for sample B, 0.80 g of ODPA and 0.22 g of TDPA was used. The contents of each flask were evacuated at 120° C. for >30 minutes, and then the flasks were heated to 320° C. under argon for 15 minutes to allow the complexation of cadmium with phosphonic acid. The reaction mixtures were cooled to 120° C. and again evacuated for 1 hour to remove water produced during the complexation. While heating back up to 320° C., 2 g of TOP was injected into each flask. Then TOPS was injected (1.95 g for sample A and 1.3 g for sample B) and the nanocrystals were grown for 85 minutes at 315° C. After cooling, toluene was added to the reaction mixtures, and the nanocrystal solutions were opened to air. The nanorods were washed several times by adding equal amounts of nonanoic acid and isopropanol—to induce flocculation—followed by centrifugation to precipitate the CdS nanorods. The supernatant was removed, and the precipitated nanorods were redispersed in fresh toluene. This reaction produces some branched structures (i.e., bipods, tripods, and tetrapods) along with the rods. However, these are removed during the washing, as the branched CdS structures do not flocculate as easily as the rods and thus stay in the supernatant.

Cation exchange of CdS nanorods. CdS nanorods in toluene were added to a solution of toluene, AgNO₃, and methanol at −66° C. in air. The reaction vials were capped after adding the CdS nanorod solution and allowed to warm to room temperature for a period of at least 30 minutes. The amounts used for a typical reaction to produce the CdS—Ag₂S superlattices were 2.0 ml of toluene, 0.6 ml of a 1.2×10⁻³ M AgNO₃ solution in methanol, 0.3 ml methanol, and 0.2 ml of CdS particles in toluene (OD ˜0.8 at λ=350 nm for 0.2 mL of the CdS toluene solution diluted to 2.2 ml with toluene). The approximate ratio of Ag⁺/Cd²⁺ to produce structures 1-4 depicted in FIG. 4 are 0, 0.14, 0.80, and 8.00. These structures were: 1 (CdS rods, Sample B), 2 (small Ag₂S islands on CdS rods), 3 (CdS—Ag₂S superlattices), and 4 (Ag₂S rods).

Characterization: Transmission electron microscopy (TEM) was carried out on an FEI Technai G2 20 Supertwin, operating at an accelerating voltage of 200 kV. The filament was LaB6.

The statistics for the length and diameter of the original CdS nanorods as well as number of Ag₂S regions per rod, center-to-center spacing, and segment lengths of the Ag₂S regions in the CdS—Ag₂S nanorod heterostructures were determined from TEM images (taken at a magnification of 97,000× to 195,000×) using Image-Pro Plus software, and making at least 250 measurements. Some superlattices contained small Ag₂S islands on the surface of the nanorod whose diameter was less than 25% of the CdS rod diameter; these islands were disregarded in the spacing measurements. Gaussian functions were used to fit the histograms. Averages and standard deviations were calculated directly from the raw data.

For the pair distribution histograms, coordinate markers were placed on the Ag₂S regions of the CdS—Ag₂S nanorod heterostructures using Image-Pro Plus software on TEM images taken at a magnification of 97,000× to 195,000×. For the partially formed Ag₂S segments (which are the majority in the low Ag⁺ case, FIG. 3A, and are a small fraction in the intermediate Ag⁺ case, FIG. 3B), the marker was placed at the center of the rod rather than the center of the Ag₂S region so that only the distance component parallel to the rod axis between Ag₂S segments is measured. This avoids error in measurement due to the 2D representation (TEM image) of a 3D object (in this case a cylindrical rod). The coordinates were then used to compute the distance between each Ag₂S region on a CdS rod with all other Ag₂S regions on that rod. These pair wise distances were measured for over 200 nanorods, to generate the histograms shown in FIG. 3. The spacings were normalized by multiplying by (n−1)/L (where n=the number of Ag₂S regions and L=sum of nearest neighbor spacings on the rod). As an Ag₂S region was found to always occur at each end of the rod, L is approximately the rod length. The bin size of the histogram was chosen as 0.07.

To estimate the volume fraction of the superlattices, the length fraction of Ag₂S segments within the superlattices was measured from TEM images for 40 nanorod superlattices. Assuming the diameters of all the segments are equal, the volume fraction is proportional to the length fraction. This gives a volume fraction of ˜36% Ag₂S, which is a slightly lower value than if 100% of the Ag⁺ added had exchanged to form Ag₂S within the rods.

Energy-dispersive X-ray spectroscopy (EDS) was collected on a Philips CM200/FEG STEM equipped with an ultra-thin window silicon EDS detector from Oxford, at the National Center for Electron Microscopy at Lawrence Berkeley National Laboratory. Spherical aberration (Cs) and chromatic aberration (Cc) were both 1.2 mm. An operating voltage of 200 kV was used with an energy dispersive x-ray detector having energy resolution of 136 eV for Mn—Kα radiation (136 eV FWHM at 5.895 keV Mn—Kα).

Powder X-ray diffraction (XRD) was taken on a PANalytical X'Pert PRO MPD with an X'Celerator detector and a copper (Cu—Kα) radiation source (1.542 Å) operating at 40 kV and 40 mA. The accumulation time for each sample was at least 4 hours with a step size of 0.0334 degrees. XRD samples were prepared by depositing a precipitated sample on a silicon plate or centrifuging the sample into a 0.3 mm Borosilicate capillary.

Fluorescence spectra were recorded on a HORIBA Jobin Yvon Fluorolog 3 equipped with a Triax 320 spectrometer at the Molecular Foundry at Lawrence Berkeley National Laboratory. The nanocrystals were precipitated and redispersed in tetrachloroethylene for the measurements. For spectra in the visible range, the excitation wavelength was 400 nm, and a photomultiplier tube (PMT) was used for detection. For the near-infrared region, the excitation wavelength was 550 nm, and a liquid nitrogen cooled InGaAs photodiode detector was used. When taking the near infrared spectra, a long-pass filter with a cutoff of 650 nm was placed in front of the detector to prevent aliasing of the excitation wavelength. The emission spectra were corrected for the wavelength-dependent response of the emission grating and detector and the background of the solvent.

Ab inito modeling: The ab initio calculations of the electronic structure of Ag₂S and CdS were performed using Vienna Ab-initio Simulation Package (VASP) and Parallel total Energy (PEtot) programs, utilizing the local density approximation (LDA) and generalized gradient approximation (GGA) to the density functional theory (DFT). We used norm-conserving pseudopotentials in order to model the electron-ion interaction (in PEtot) as well as projector-augmented wave (PAW) method (in VASP). Planewave basis sets are used with kinetic energy cutoffs ranging from 20 to 75 Ry, with Monkhorst-Pack k-point meshes to sample the Brillouin zone (up to 256 reducible points). These techniques were used to estimate stability of various Ag₂S phases, find the optimal geometry for the epitaxial attachment, calculate the formations energies of the CdS—Ag₂S interfaces, and calculate the corresponding band alignment. For the interface calculations the supercells were constructed containing 20 S, 12 Cd, and 16 Ag atoms, with their positions fully relaxed using ab initio forces. The band alignment was estimated by comparing the site-projected densities of states (DOS) of the most bulk-like S atoms in the supercell (in Ag₂S and CdS slabs) with the site-projected DOS of the bulk Ag₂S and CdS. The shift in valence band DOS from their bulk values is then equal to the valence band alignment for the interface. The conduction band alignment is obtained by adding the bulk experimental band gap value to the valence band energy in order to overcome the known tendency of the LDA/GGA to underestimate the value of the band gap.

The elastic constants of the Ag₂S bulk crystal were also estimated using the ab initio methods outlined above. The elastic constants Cij were computed by distorting the crystal in corresponding directions and fitting the total energy into the second order elastic expansions.

VFF modeling: Elastic energies and strains were estimated using the Valence Force Field (VFF) method, which is an atomistic bond stretching and bending model. The VFF model parameters for CdS are available in the literature, while the parameters for the experimentally observed Ag₂S phase were obtained by fitting the elastic constants of Ag₂S obtained from the ab initio calculations into the VFF. A CdS nanorod was constructed to have two inclusion segments of a different material with a lattice mismatch and the elastic constants corresponding to the CdS—Ag₂S nanorod superlattice. All the atomic positions were relaxed according to the VFF model, and the elastic energy after the relaxation was calculated. This was done for several segment-segment separation distances. The nanorod diameter was 4.8 nm.

To understand the repulsive elastic energy it is necessary to understand that the VFF model relaxes atoms in all directions. In a simplified 1D model there would be no interaction energy between two islands; each island would add elastic energy based solely on the distance from the interface regardless of the strain induced by the other. For a single segment, the elastic strain field decays roughly exponentially from the interface as ˜exp [−x/(βd)], where x is the distance from the interface measured along the length of the rod, d is the nanorod diameter, and β is a constant. The elastic energy is proportional to the square of the elastic strain field, but the force is a derivative of the energy, leaving a linear relation between the force and strain created by an island. Calculations show that no higher order terms occur in the energy expression. If another segment were to apply a strain near the first segment the two forces would add directly, as if each were acting independently. Thus there is no interaction between the islands from a 1D perspective. However, since the VFF modeling is 3D, atomic movements in the other spatial directions exhibit considerable influence on the overall energy, creating the interaction terms that lead to higher energy as the inclusion segments approach each other.

XRD simulation: The powder patterns expected from a mixture of short CdS (5.3×11 nm; wurtzite, JCPDS #41-1049) rods and Ag₂S nanocubes (edge length=5.0 nm; monoclinic, Acanthite JCPDS #14-0072) was simulated. Those domain sizes were chosen to mimic the approximate volumes and shapes seen in TEM images for alternating CdS and Ag₂S domains. The simulated patterns provide a reference for the experimental nanorod superlattice patterns obtained.

For each of the two nanocrystalline domains under consideration, the computation proceeds as follows. Given the desired shape and crystal phase, the Cartesian positions of atoms constituting the nanocrystal was calculated. (No defects/strain were allowed for in the calculations.) The atomic positions were used to calculate a list of all pairwise interatomic distances (rᵢⱼ, with i and j denoting i-th and j-th atoms). This list on its own is sufficient for an exact calculation of the powder pattern. For computational efficiency, however, the list of distances was binned into a histogram. Then, an extension of the below approximate expression yields the expected powder XRD intensity profile,

$$I ( S ) ∝ \frac{{F}^{2} ( S )}{S} {\sum }_{k}^{N} \frac{{p}_{k}}{{r}_{k}} sin ( 2 π {r}_{k} S )$$

where S=2 sin(θ)/λ is the scattering parameter, I(S) is the observed intensity, rₖ is the value of r at center of a ‘bin’ and pₖ is the number of occurrences of interatomic distances falling within the bin centered around rₖ. N is the total number of bins. F(S) is the atomic structure factor, in our case, of cadmium, silver, and sulfur. The bin widths are small enough that the simulated pattern is insensitive to further decrease of the bin width (˜0.001 Å). Note that the expression given above is a simple form that applies to particles made of only one chemical species. For our multi-species particles, we used a straightforward extension with F(S) being replaced in the correct expression by three different appropriate atomic structure factors, in our case, of cadmium, silver, and sulfur.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

What is claimed is:

1. A method comprising:
forming a mixture comprising nanorods comprising a first material comprising first ions, coordinating molecules, and second ions in a solvent; and
forming composite nanorods in the solvent, wherein each composite nanorod comprises a linear body comprising a first region comprising the first material and a second region comprising a second material, wherein the second material comprises the second ions.

2. A method comprising:
forming a mixture comprising nanorods comprising a first material comprising first cations and first anions, coordinating molecules, and second cations and second anions in a solvent; and
forming composite nanorods in the solvent, wherein each composite nanorod comprises a linear body comprising a first region comprising the first material and a second region comprising a second material, wherein the second material comprises the second cations and first anions.

3. The method of claim 2 wherein the mixture has a second ion/first ion ratio between about 0 and 5.

4. The method of claim 2 wherein the first and second ions include at least one transition metal from rows I, II, III, IV, or V of the periodic table.

5. The method of claim 2 wherein the first and second materials are ionic compounds.

6. The method of claim 2 wherein the coordinating molecules comprise alcohols.

7. The method of claim 2 further wherein the nanorods are present as arms in two or three-dimensional nanoparticles.

8. The method of claim 2 further comprising:
forming the nanorods prior to forming the mixture.

9. The method of claim 2 further comprising maintaining the mixture at less than zero degrees Celsius, and then allowing the mixture to warm to room temperature.

10. A one-dimensional nanostructure, comprising:
a repeat nanostructure unit comprising:
a first layer comprising a first material; and
a second layer comprising a second material adjacent the first layer;
wherein a series of repeat units are arranged adjacent one another linearly to form a nanostructure superlattice.

11. The nanostructure of claim 10 wherein the thickness of the first layer in the repeat unit is approximately the same throughout the nanostructure.

12. The nanostructure of claim 10 wherein the thickness of the second layer in the repeat unit is approximately the same throughout the nanostructure.

13. A composite nanorod comprising:
a linear body including at least four alternating regions including a first region and a second region, wherein the first region comprises a first material comprising a first ionic compound and the second region comprises a second material comprising a second ionic compound.

14. A two or three-dimensional nanoparticle comprising the composite nanorod of claim 13.

15. The nanorod of claim 13, wherein the first material comprises a first ionic material and the second material comprises a second ionic material.

16. The nanorod of claim 13, wherein the nanorod has a length less than approximately 200 nanometers.

17. The nanorod of claim 13, wherein the first ionic compound comprises a non-noble metal ion and the second ionic compound comprises a noble metal ion.

18. The nanorod of claim 13, wherein the nanorod comprises a diameter less than about 15 nanometers.

19. The nanorod of claim 13, wherein the first material comprises CdS and the second material comprises Ag₂S.
